(19) United States
(12) Patent Application Publication
(10) Pub. No.: US 2025/0267911 A1
(43) Pub. Date: Aug. 21, 2025

(54) DISCONTINUOUS BARRIER FILM BETWEEN EMITTER AND BASE OF BIPOLAR TRANSISTOR

(71) Applicant: GlobalFoundries Singapore Pte. Ltd., Singapore (SG)

(72) Inventors: Sicong Chen, Singapore (SG); Seow Wei Lai, Singapore (SG); Christopher Teck Wee Lim, Singapore (SG); Jingyan Huang, Singapore (SG); Kangjian Cheng, Singapore (SG); Shyue Seng Tan, Singapore (SG); Xinshu Cai, Singapore (SG); Kien Seen Daniel Chong, Singapore (SG)

(21) Appl. No.: 18/442,188

(22) Filed: Feb. 15, 2024

(51) Int. Cl. H01L 29/10; H01L 29/737

(52) U.S. Cl. CPC H10D 62/177; H10D 10/861

(57) ABSTRACT

The disclosure provides structures and methods to provide a discontinuous barrier film between an emitter and base of a bipolar transistor. A structure according to the disclosure includes a discontinuous barrier film vertically interposed between an emitter and a base of a heterojunction bipolar transistor. Methods of the disclosure include: forming a collector terminal within a semiconductor substrate; forming a base terminal on the collector terminal; forming a discontinuous barrier film on the base terminal; and forming an emitter terminal over the base terminal and the discontinuous barrier film to define a bipolar transistor. The discontinuous barrier film is vertically interposed between the emitter terminal and the base of the bipolar transistor.

### BACKGROUND

The present disclosure relates to bipolar junction transistors (also known simply as “bipolar transistors”) and methods of forming bipolar junction transistors.

The structure of a bipolar transistor defines several of its properties during operation. Breakdown voltage from base to emitter in a bipolar transistor, in particular, may limit the ability to practically deploy certain bipolar transistor architectures in various products and/or operational settings. Certain processing techniques may induce diffusion of dopants from emitter to base at smaller scales, e.g., thermal processing of the emitter in a vertically-oriented bipolar transistor.

### SUMMARY

The illustrative aspects of the present disclosure are designed to solve the problems herein described and/or other problems not discussed.

Embodiments of the disclosure provide a structure including: a discontinuous barrier film vertically interposed between an emitter and a base of a bipolar transistor.

Other embodiments of the disclosure provide a structure including: a heterojunction bipolar transistor (HBT) structure including: a collector terminal within a semiconductor substrate; a base terminal on the collector terminal; an emitter terminal over the base terminal; and a discontinuous barrier film vertically interposed between the emitter terminal and the base of the heterojunction bipolar transistor.

Additional embodiments of the disclosure provide a method including: forming a collector terminal within a semiconductor substrate; forming a base terminal on the collector terminal; forming a discontinuous barrier film on the base terminal; and forming an emitter terminal over the base terminal and the discontinuous barrier film to define a bipolar transistor, wherein the discontinuous barrier film is vertically interposed between the emitter terminal and the base of the bipolar transistor.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view of a structure according to embodiments of the disclosure.

FIG. 2 depicts an expanded cross-sectional view of a discontinuous barrier film between an emitter and base of a bipolar junction transistor according to embodiments of the disclosure.

FIG. 3 depicts forming an initial insulator on a base in methods according to embodiments of the disclosure.

FIG. 4 depicts removing an initial oxide according to embodiments of the disclosure.

FIG. 5 depicts forming a discontinuous barrier film according to embodiments of the disclosure.

FIG. 6 depicts forming an emitter according to embodiments of the disclosure.

FIG. 7 depicts planarizing the emitter according to embodiments of the disclosure.

FIG. 8 depicts removing portions of the emitter and insulator to prepare for extrinsic base formation according to embodiments of the disclosure.

FIG. 9 depicts forming additional insulator according to embodiments of the disclosure.

FIG. 10 depicts forming extrinsic bases according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides structures and methods to provide a discontinuous barrier film between an emitter and base of a heterojunction bipolar transistor (HBT). A structure according to the disclosure includes a discontinuous barrier film vertically interposed between an emitter and a base of a heterojunction bipolar transistor. In embodiments of the disclosure, the barrier film (including, e.g., one or more oxide-based insulative materials) may be “discontinuous” by not extending completely over the material(s) on which it is formed. Discontinuous barrier films may include, e.g., vacancies, apertures, etc., that may be filled with any material(s) subsequently formed on the discontinuous barrier film. In structures where a discontinuous barrier film is defined along the physical boundary between a first material and a second material, the discontinuous barrier film may separate the first material from the second material along some areas of the physical boundary whereas the first material may be in contact with the second material in other areas of the physical boundary.

Bipolar junction transistor (BJT) structures, such as those in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may be contingent on the type and magnitude of bias applied to the material composition of one or both terminals, which affects the size of the potential barrier. In the case of a junction between two semiconductor materials, the potential barrier will be formed along the interface between the two semiconductor materials.

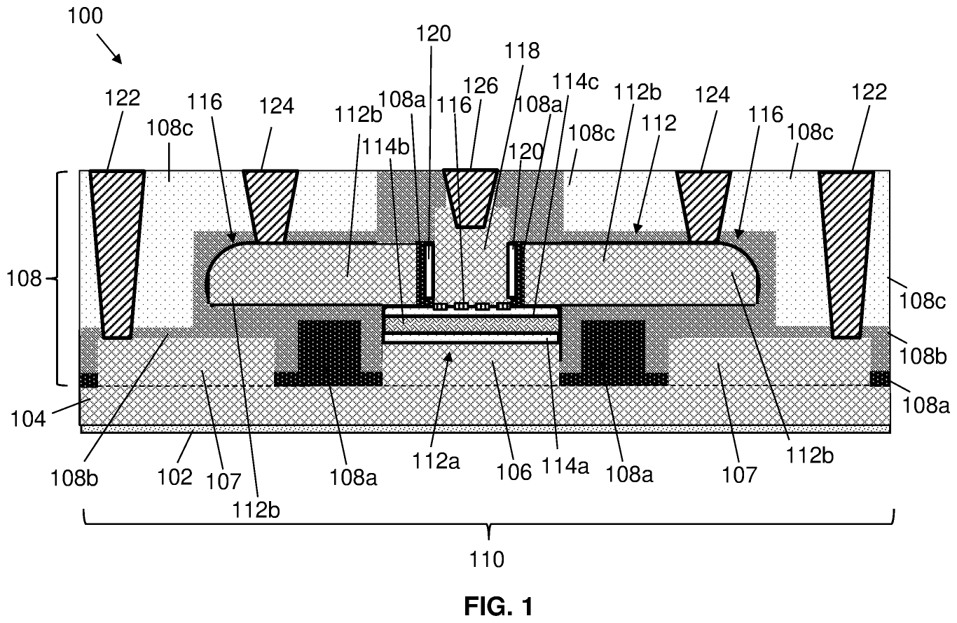

Referring to FIG. 1, a structure 100 according to the disclosure may include a bipolar transistor 110 (e.g., a vertically oriented heterojunction bipolar transistor (“HBT”) as discussed herein) and an insulator 108 horizontally adjacent bipolar transistor 110. Various embodiments of the disclosure disclosed herein include a discontinuous barrier film 116 (e.g., one or more insulative materials such as oxide-based insulators) on a base terminal of bipolar transistors. The presence of discontinuous barrier films on the base of a transistor may impede or prevent dopant diffusion between oppositely doped layers of material as the bipolar transistor is manufactured, but do not interfere with the passage of currents across the base-emitter junction during operation of a device. Structure 100 may be formed on a substrate 102 including, e.g., one or more monocrystalline semiconductor materials. Substrate 102 may include but is not limited to silicon, germanium, silicon germanium (SiGe), silicon carbide, or any other currently known or later developed IC semiconductor substrates. In the case of SiGe, the germanium concentration in substrate 102 may differ from other SiGe-based structures described herein. A portion or entirety of substrate 102 may be strained. Substrate 102 may be doped to provide a subcollector 104 (also known as a “doped well” to indicate a lower region of semiconductor material having dopants), e.g., to enable coupling to the lower active semiconductor materials of a vertical bipolar transistor. Subcollector 104 may have any conceivable doping type and/or doping composition appropriate for use within and/or coupling to the collector terminal of a bipolar transistor. For instance, subcollector 104 may have the same dopant type as other portions of substrate 102 (e.g., P type doping), a different doping type, similar or different doping species, and/or may have a higher or lower higher dopant concentration therein.

A collector (also known as a “collector terminal”) 106 may be on subcollector 104, e.g., a as a single layer or multiple horizontally separated and distinct layers formed by deposition and/or epitaxial growth of silicon and/or other semiconductor materials on subcollector 104 and may have a predetermined doping type, e.g., by being doped in-situ or during formation of semiconductor material(s) of substrate 102 and/or subcollector 104. Collector 106 may define active semiconductor material of a vertical bipolar transistor, and thus may be vertically below other terminals (i.e., intrinsic base, extrinsic base, and emitter terminals discussed herein) of bipolar transistor 110. Collector extension regions 107 (i.e., additional semiconductor regions having the same doping type and/or composition as collector 106) also be on subcollector 104 to facilitate forming of electrical coupling of collector contacts (contacts 122 discussed herein) to collector 106. In some cases, collector extension regions 107 may be known as “collector contact regions” in the case where one or more contacts are formed thereon. An insulator 108, which may be subdivided into multiple layers and/or materials, may also be on subcollector 104 to horizontally separate various portions of collector 106 from each other but enabling electrical interconnection of each collector 106 through subcollector 104 thereunder.

Insulator 108 may include multiple layers, the composition of which may optionally vary between embodiments. For instance, insulator 108 as shown in FIG. 1 may include a first insulator 108a (e.g., a trench isolation (TI) structure and/or other oxide based insulator such as silicon oxide (SiO2)) on subcollector 104 on opposing sides of collector 106 (e.g., separating collector 106 from collector extension regions 107) and a second insulator 108b on first insulator 108a (e.g., a spacer material such as silicon nitride (SiN) or other nitride based insulators). Second insulator 108b, where provided, may encapsulate the various components of bipolar transistor 110. A third insulator 108c may be on, and adjacent portions of, second insulator 108b. Third insulator 108c may have the same composition as first insulator 108a or may have a different composition, e.g., it may be another layer of SiO2 or any other currently know or later developed middle of line (MOL) or back end of line (BEOL) insulator materials). In various further implementations, only one of the multiple insulators 108a, 108b, 108c may be used to provide insulator 108. Where each of insulators 108a, 108b, 108c are included, insulator 108 may take the form of an oxide-nitride-oxide (“ONO”) stack over substrate 102.

Bipolar transistor 110 may include a base 112 on collector 106. Base 112 may be subdivided into various layers having distinct positions and/or material compositions. Base 112 may include an intrinsic base 112a on an upper surface of collector 106. Intrinsic base 112a may include multiple distinct layers, e.g., a first layer 114a including crystalline silicon (Si) with a low amount of doping (e.g., p-type), a second layer 114b on first layer 114a and including monocrystalline silicon germanium (SiGe), also with a relatively low amount of doping (e.g., p-type), and a third layer 114c on second layer 114b. Third layer 114c also may include crystalline Si and thus may have the same composition and/or doping as first layer 114a, or otherwise may be compositionally similar to first layer 114a. The presence of a different material (e.g., SiGe) in second layer 114b from layers 114a, 114c (e.g., Si) may provide an HBT structure, but in other configurations of bipolar transistor 110, the composition of intrinsic base 112a may be substantially uniform (e.g., it may include only doped Si). Although intrinsic base 112a is shown by example to have three layers 114a, 114b, 114c, a larger or smaller number of individual layers may be provided. In some cases, intrinsic base 112a may have only one layer (e.g., a single layer of SiGe similar to the composition of second layer 114b). The layer(s) 114a, 114b, 114c of intrinsic base 112a may arise from being formed by selective epitaxial growth of monocrystalline semiconductor materials (e.g., Si and/or SiGe as discussed herein) on collector 106 between portions of insulator 108a, 108b.

Base 112 also may include one or more extrinsic bases 112b (two shown) on portions of intrinsic base 112a. Extrinsic bases 112b may be on a portion of intrinsic base 112a but are horizontally distal to other transistor terminals (e.g., emitter 118 discussed herein) that are also on intrinsic base 112a. Extrinsic bases 112b may include monocrystalline silicon with a relatively high amount of the same doping type (e.g., more p-type doping than intrinsic base 112a). Extrinsic base(s) 112b may be located, e.g., partially over the opposing horizontal ends of intrinsic base 112a and may further protrude horizontally outward from the opposing horizontal ends of intrinsic base 112a over insulator 108a and further over insulator 108b so as to partially overlay but be electrically isolated from collector extension regions 107. The shape of extrinsic base 112b may arise from being formed by selective epitaxial growth of monocrystalline semiconductor material on exposed semiconductor surfaces such that it further extends over portions of insulator 108 (e.g., portions 108a) on opposing sides of collector 106 and intrinsic base 112a thereon, during processing as discussed herein. Intrinsic base 112a and extrinsic base 112b together may define base 112, also known as a “base terminal” of bipolar transistor 110.

Intrinsic base 112a and extrinsic base 112b of base 112 may have different material compositions and doping concentrations but may have a uniform doping polarity. In the case where the bipolar transistor 110 is an NPN-type transistor and subcollector 104, collector 106, and collector extension region(s) 107 are doped n-type, base 112 may be doped p-type to form a P-N junction, and hence an emitter/collector interface. It is also understood that base 112 may be doped n-type in the case where the bipolar transistor is a PNP-type transistor.

Structure 100 includes bipolar transistor 110 with a discontinuous barrier film 116 on base 112, such that discontinuous barrier film 116 is vertically interposed between base 112 and an emitter (also known as an “emitter terminal”) 118 thereon. Discontinuous barrier film 116 may include one or more insulators, e.g., an oxide-based material such as silicon dioxide (SiO2) and/or similar insulative oxide-base materials, or other currently known or later developed insulators in the form of a discontinuous film. The forming of discontinuous barrier film may include, e.g., successive deposition and thermal treatment of insulator (e.g., oxide) layers such that discontinuous barrier film 116, when formed, does not significantly impede passage of current from base 112 to emitter 118 thereover. Discontinuous barrier film 116, however, has sufficient presence to impede diffusion of dopants from emitter 118 to base 112 or vice versa in later phases of processing. As discussed elsewhere herein, the forming of discontinuous barrier film 116 may include successive chemical treatments, e.g., forming an oxide (or other insulator) layer on intrinsic base 112a, applying a first chemical treatment to the barrier film (e.g., in the case of oxide-based materials, contacting the layer with a mixture of ammonia, hydrogen peroxide, and deionized water), and optionally applying further chemical treatments to the treated barrier film (e.g., in the case of oxide-based material, contacting the layer with a mixture of hydrochloric acid, hydrogen peroxide, and deionized water). The chemical treatment(s) are operable to remove only some portions of the initial barrier film from intrinsic base 112a, while other portions of the barrier film will remain intact due to the rates of reaction and/or amount(s) of reactants applied. Such techniques may yield discontinuous barrier film on intrinsic base 112a. The reactants used to form discontinuous barrier film 116 may be selected to control the amount of remaining insulator (e.g., oxygen content) and/or the size of discontinuous barrier film 116 over base 112. In implementations where discontinuous barrier film 116 is oxide-based, it may have an oxygen concentration of between approximately 1E20 (where “E” denotes ten with an exponent of the following value) and 1E21 atoms per cubic centimeter. The concentration of oxygen within discontinuous barrier film 116 may be locationally dependent, i.e., it may be non-uniform over base 112 as a result of the successive chemical treatments.

As noted herein, discontinuous barrier film 116 is considered “discontinuous” by not extending completely over the portion of intrinsic base 112a on which it is formed. Discontinuous barrier film 116 thus may include, e.g., vacancies, apertures, etc., that may be filled with portions of emitter 118 subsequently formed on discontinuous barrier film 116. Discontinuous barrier film 116 may be vertically interposed between base 112 and emitter 118 in some locations, but base 112 physically contacts emitter 118 thereover in other locations despite the presence of discontinuous barrier film 116 elsewhere.

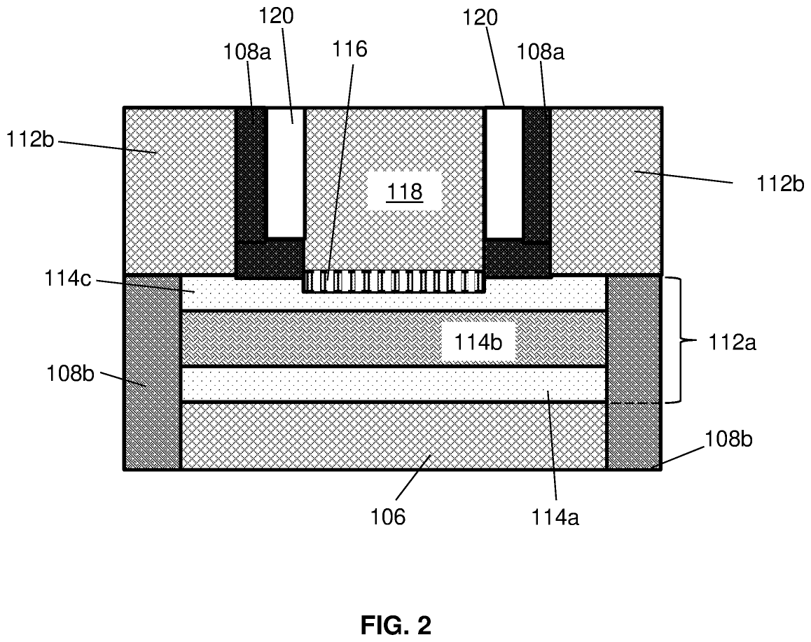

Emitter 118 may be on intrinsic base 112a and may have the same doping type as subcollector 104 and collector 106, and thus, has an opposite doping type relative to base region 112. In the case where bipolar transistor 110 is an NPN device, collector 106 and emitter 118 may be doped n-type to provide the two n-type active semiconductor materials and base 112 (including intrinsic base 112a and extrinsic base 112b thereof) may be doped p-type. Emitter 118 may include a semiconductor with any dopant(s) for providing the desired conductivity type. For n-type doping, emitter 118 may include Si doped with arsenic (As) ions, i.e., arsenic-doped silicon (As—Si). Emitter 118 may be formed by deposition and doping of semiconductor material(s) (e.g., Si). The dopant ions within emitter 118 (e.g., As) conventionally, may be able to migrate into base 112 as emitter 118 is formed. The presence of discontinuous barrier film 116 may impede, or entirely prevent, dopant migration from emitter 118 into base 112. Further structural details of discontinuous barrier film 116 vertically between base 112 and emitter 118 are shown in FIG. 2 and discussed elsewhere herein.

One or more spacers 120 may be adjacent emitter 118 to structurally and electrically separate emitter 118 from extrinsic base 112b and/or contacts formed thereto. Spacer(s) 120 may include a nitride insulative material and/or any other insulative material discussed herein, e.g., insulator 108 or other insulating structures. As discussed in more detail herein, spacer(s) 120 be formed, e.g., by depositing a spacer material such that it covers any exposed surfaces and inner sidewalls of extrinsic base 112b and any portions of insulator(s) 108b, 108c thereover before other materials (e.g., emitter 118) are formed over base 112. In some implementations, spacer(s) 120 may include a single layer or more than two layers.

To electrically couple bipolar transistor 110 to other devices and/or structures, a set of collector contacts 122 may extend through insulator 108 to collector extension region(s) 107, a set of base contacts 124 may extend through insulator 108 to extrinsic base(s) 112b, and one or more emitter contacts 126 may extend through insulator 108 to emitter 118. Contacts 122, 124, 126 may have similar or identical compositions, e.g., they may include conductive metals such as aluminum (Al), copper (Cu), gold (Au), etc. Contacts 122, 124, 126 thus may be distinguishable from each other solely based on the materials to which they connect, e.g., each contact 122 is on collector extension region 107, each contact 124 is on extrinsic base 112b, and each contact 126 is on emitter 118.

FIG. 2 depicts an expanded cross-sectional view of structure 100 to describe relative positions of intrinsic base 112a, emitter 118, and discontinuous barrier film 116 therebetween in more detail. As shown, discontinuous barrier film 116 is made up of a plurality of individual, disconnected portions located at various points along a horizontal span of intrinsic base 112a. Structure includes two portions of first insulator 108a each adjacent an opposite sidewall S1, S2 of emitter 118. A first spacer 120a may be on first insulator 108a and horizontally adjacent sidewall S1 of emitter 118. A second spacer 120b may be on first insulator 108a and adjacent sidewall S2 of emitter 118. The various portions of discontinuous barrier film 116 are each located on an area of intrinsic base 112a that is horizontally between first spacer 120a and a second spacer 120b, and any portions of first insulator 108a therebelow. First spacer 120a and second spacer 120b may be substantially identical, in which case they are distinguished from each other solely based on their relative positions on opposite sides of emitter 118.

Discontinuous barrier film 116 may extend horizontally between the portions of first insulator 108a, and thus may be below first spacer 120a and second spacer 120b. There are several locations long the span where emitter 118 is directly over intrinsic base 112a, and thus multiple As—Si to Si physical interfaces are present along the length of discontinuous barrier film 116 between insulator(s) 108a. There are also several locations where portions of discontinuous barrier film 116 are vertically interposed between intrinsic base 112a and emitter 118. The individual portions of discontinuous barrier film 116 vertically interposed between intrinsic base 112a and emitter 118, collectively, may occupy at least half of the horizontal span between first spacer 120a and second spacer 120b. Where intrinsic base 112a includes Si and emitter 118 includes As-doped Si (As—Si), there may be at least one As—Si to Si interface where intrinsic base 112a meets emitter 118 between portions of discontinuous barrier film 116. Thus, discontinuous barrier film 116 retains at least some physical coupling between intrinsic base 112a and emitter 118.

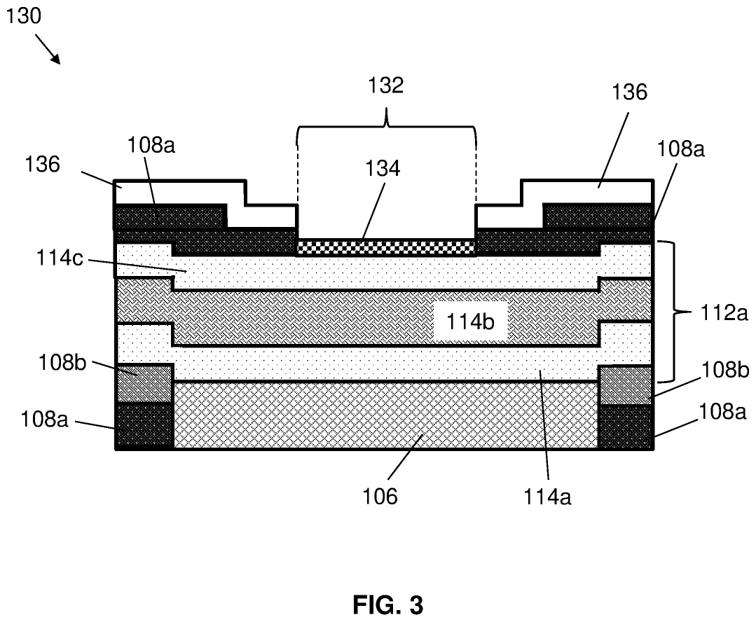

Referring now to FIG. 3, embodiments of the disclosure also provide various methods to form structure 100 (FIGS. 1, 2). Such methods may be compatible with a variety of conventional processes to form vertically oriented bipolar transistors (including, e.g., HBTs) but may include certain modifications to provide discontinuous barrier film 116 on a portion of intrinsic base 112a (FIGS. 1, 2) before forming emitter 118 (FIGS. 1, 2). Methods of the disclosure are operable to form structure 100 and bipolar transistor 110 (FIGS. 1, 2) in a variety of configurations, and one such configuration is shown and discussed herein as an example. FIG. 2 depicts an initial structure 130 capable of being processed to yield embodiments of structure 100 discussed herein. Initial structure 130 may include, horizontally between portions of first insulator 108a and second insulator 108b as discussed herein, collector 106.

Intrinsic base 112a may be on collector 106 and adjacent portions of insulator(s) 108a, 108b. In cases where insulator(s) 108a, 108b extend to a height above collector 106, intrinsic base 112a and its layers 114a, 114b, 114c may be substantially U-shaped. At this stage of processing, intrinsic base 112a may include layers 114a, 114b, 114c therein but extrinsic base 112b (FIGS. 1, 2) has not yet been formed. Another portion of first insulator 108a may be on second insulator 108b and over intrinsic base 112a. More specifically, portions of first insulator 108a may contact and overlie an uppermost layer (e.g., third layer 114c including crystalline Si) of intrinsic base 112a. Insulator(s) 108a, 108b may be formed by conventional techniques, e.g., depositing layers of insulative material and removing the deposited layer(s) with the aid of a temporary etch mask.

First insulator 108a initially may be formed as a layer over intrinsic base 112a, before portion of first insulator 108a is removed (e.g., by targeted etch) to provide an opening 132 within first insulator 108. Opening 132 initially may expose an uppermost surface of intrinsic base 112a. Further processing may include forming (e.g., by selective deposition on Si material) a preliminary insulator 134, e.g., one or more oxide layers or other layer(s) of insulative material, on intrinsic base 112a. Further processing may include forming a spacer layer 136 (e.g., one or more nitride-based insulators and/or other insulative materials) on first insulator 108. Spacer layer 136 may be formed by deposition, such that it covers all surfaces and sidewalls of preliminary structure 130 (FIG. 3). After forming spacer layer 136, it may be processed by selective and/or downward etching such that it remains intact on first insulator 108a but is removed from over preliminary insulator 134. The partial removing of spacer layer 136 to form spacers 120 (e.g., first spacer 120a, 120b discussed herein) may be implemented through the use of nitride-selective etchants and/or other etching techniques that will not affect the composition (e.g., oxide based materials) of first insulator(s) 108a or preliminary insulator 134. In other implementations, spacer layer 136 may be formed before preliminary insulator 134, but targeted portions of spacer layer 136 on third layer 114c may be removed and replaced with preliminary insulator 134 Opening 132 may have a substantially rectangular shape for forming crystalline semiconductor material therein in subsequent processing.

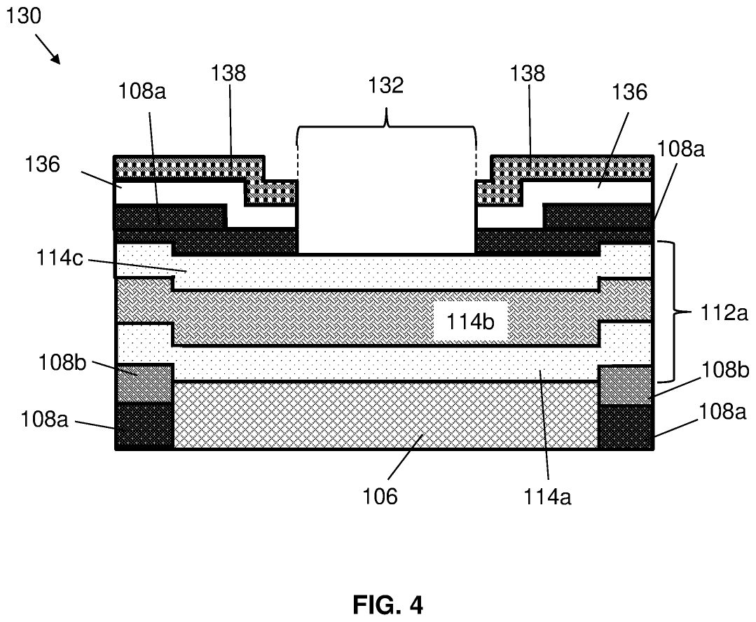

FIG. 4 depicts further processing to re-expose intrinsic base 112a. Specifically, preliminary insulator 134 (FIGS. 3-5) may be removed by downward etching by materials selective to preliminary insulator 134 composition. Preliminary masks 138 may be formed on first insulator 108a outside opening 132, e.g., to protect first insulator 108a from being removed concurrently with preliminary insulator 134. Preliminary mask(s) 138 may include any currently known or later developed photoresist material (e.g., one or more nitride based hard mask layers) having a predetermined horizontal width Preliminary masks 138 may be removed by stripping after preliminary insulator 134 is removed.

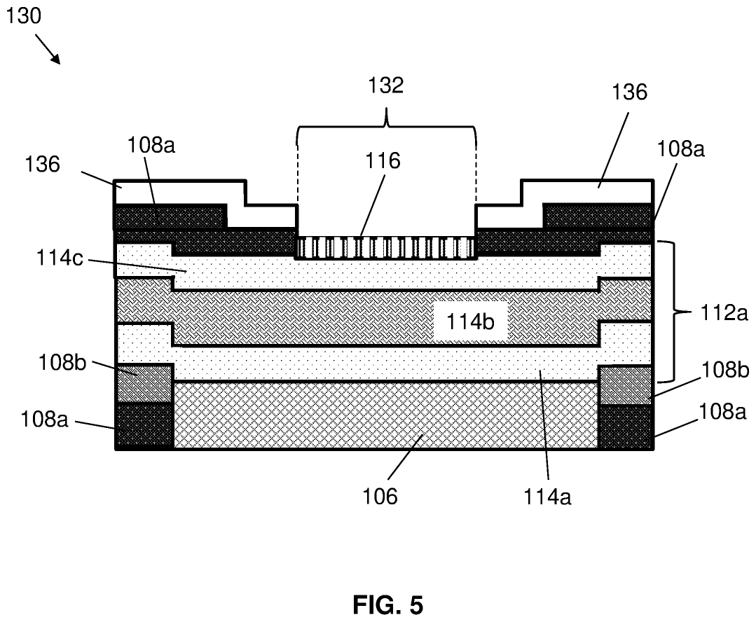

Turning now to FIG. 5, further processing may include forming discontinuous barrier film 116 on intrinsic base 112a by chemically treating intrinsic base 112a (e.g., at third layer 114c). Discontinuous barrier film 116 may be processed to yield a thin layer (i.e., less than approximately 2.50 nanometers (nm) on, or from, exposed portions of intrinsic base 112a. Discontinuous barrier film 116 thus may extend continuously over intrinsic base 112a from one portion of first insulator 108a to another, and without abutting spacer layer(s) 136.

Discontinuous barrier film 116 can be produced by applying a first chemical treatment to intrinsic base 112a (e.g., in the case of oxide-based materials, contacting intrinsic base 112a with a mixture of ammonia, hydrogen peroxide, and deionized water), and optionally applying further chemical treatments to the treated intrinsic base 112a (e.g., in the case of oxide-based material, contacting the layer with a mixture of hydrochloric acid, hydrogen peroxide, and deionized water).

The chemical treatment(s) react with only some portions of intrinsic base 112a, while other portions of the barrier film 140 will remain intact due to the rates of reaction and/or number(s) (s) of reactants applied. Such techniques may yield discontinuous barrier film 116 on intrinsic base 112a. The reactants used to form discontinuous barrier film 116 may be selected to control the amount of remaining insulator (e.g., oxygen content) and/or the size of discontinuous barrier film 116 over base 112. In implementations where discontinuous barrier film 116 is an oxide-based material, it may have an oxygen concentration of between approximately 1E20 (where “E” denotes ten with an exponent of the following value) and 1E21 atoms per cubic centimeter. The concentration of oxygen within discontinuous barrier film 116 may be locationally dependent, i.e., it may be non-uniform over base 112 as a result of the successive chemical treatments. Discontinuous barrier film 116, once formed, may cover a majority of the span of intrinsic base 112a within opening 132. Discontinuous barrier film 116 thus includes various apertures, openings, etc., allowing subsequent materials to be formed on any exposed portions of intrinsic base 112a thereunder.

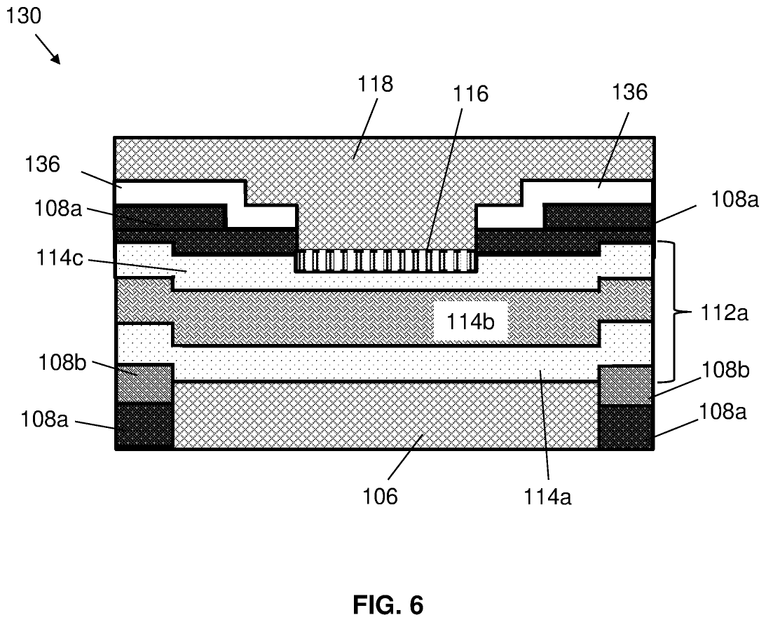

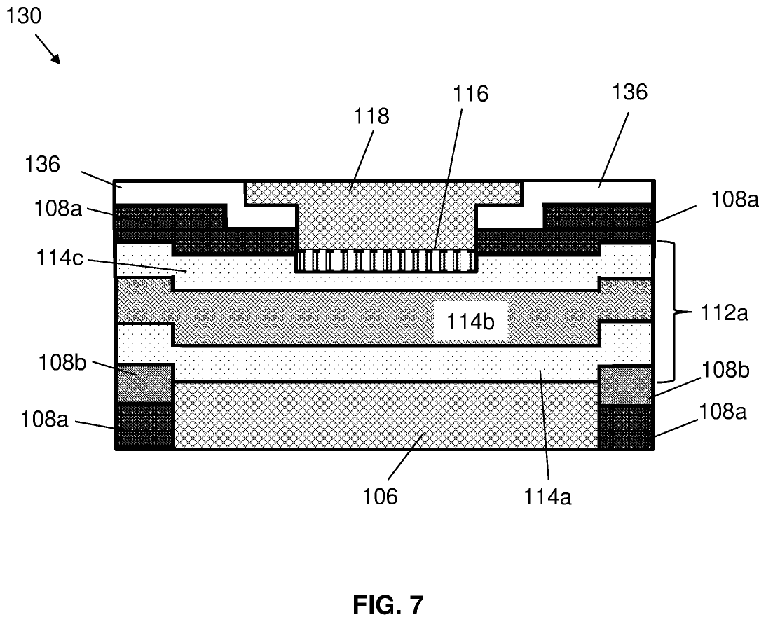

FIGS. 6 and 7 depict forming of additional epitaxial semiconductor material within opening 132 (FIGS. 3-5) and elsewhere to form emitter 118, e.g., by further epitaxial growth and/or deposition of n-type semiconductor material(s) on intrinsic base 112a, notwithstanding the presence of discontinuous barrier film 116. The same epitaxial growth process(es) may form additional emitters and/or n-type semiconductor materials of a device located outside structure 100. The presence of discontinuous barrier film 116 will not impede the forming of n-type semiconductor materials to provide emitter 118 thereover, and various portions of emitter 118 may extend through openings in discontinuous barrier film 116. Third layer 114c (e.g., crystalline Si), or another uppermost layer of intrinsic base 112a thus may function as a seed layer for emitter 118 even though portions of barrier film 116 cover intrinsic base 112a. Emitter 118 may be formed to fill opening 132. Emitter 118, initially, may cover and overlie adjacent portions of first insulator 108a and spacer layer 136. As shown specifically in FIG. 7, emitter 118 thereafter may be planarized (e.g., by CMP) such that its upper surface is substantially coplanar with adjacent upper surfaces of spacer layer 136. In some cases, emitter 118 may extend beyond the upper surfaces of spacer layer 136, e.g., where additional portions of second insulator 108b are located above spacer layer 136 (see, e.g., FIG. 1). In any case, the presence of discontinuous barrier film 116 may prevent any dopant(s) from emitter 118 from migrating (e.g., when subjected to heat and pressure during deposition and/or subsequent processing) into intrinsic base 112a.

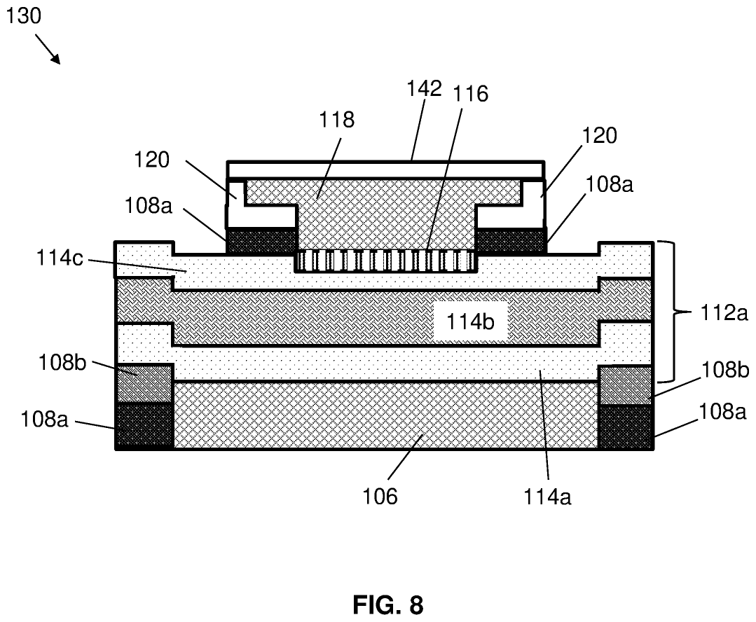

FIG. 8 depicts forming a capping insulator 142 to cover emitter 118 and adjacent portions of spacer layer 136 (FIGS. 3-7) to enable the removing of adjacent insulative materials. Masking layer 142 may include a nitride and/or oxide-based insulator or may be similar to other masking layers discussed herein (e.g., one or more nitride based hard mask layers) having a predetermined horizontal width. Capping insulator 142 may entirely cover emitter 118 and some portions of adjacent material but may not extend beyond the horizontal edge(s) intrinsic base 112a. Any portions of first insulator(s) 108a and spacer layer 136 not covered by masking layer 142 can be removed (e.g., by directional etch) to expose intrinsic base 112a and second insulator(s) 108b thereunder, thereby forming spacers 120.

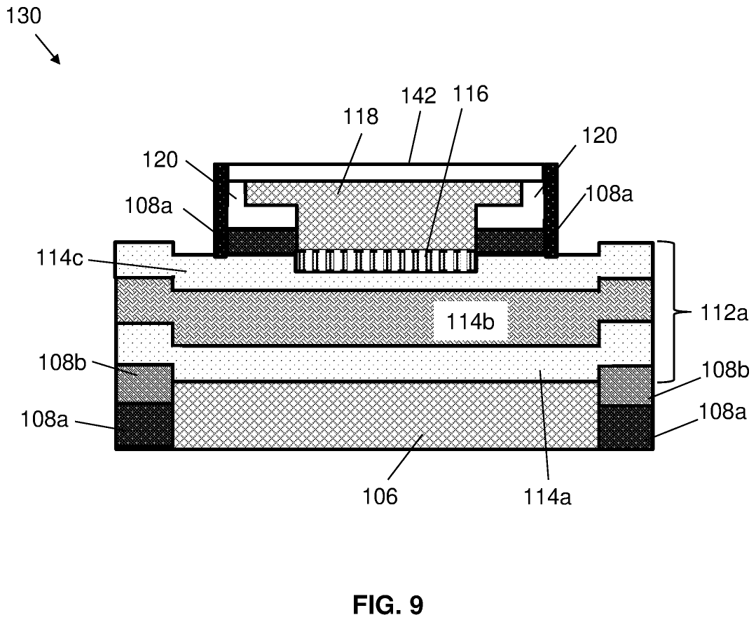

FIG. 9 depicts a process to further insulate emitter 118 from adjacent materials, e.g., subsequently formed extrinsic bases 112b (FIGS. 1, 2). For example, embodiments of the disclosure may include forming additional portions of first insulator 108a, e.g., by forming a layer of oxide-based or other insulative materials and directionally etching the layer such that only first insulator 108a remains on sidewalls of spacers 120 and capping insulator 142.

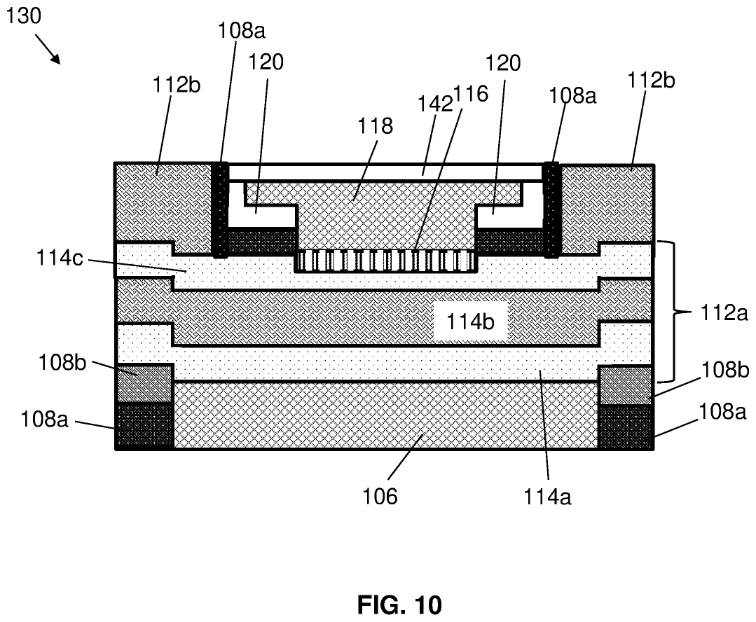

Turning to FIG. 10, further processing may include forming extrinsic bases 112b on intrinsic base 112a (e.g., on third layer 114c thereof) by epitaxial growth of semiconductor material having a same doping type as intrinsic base 112a (e.g., p-type) but with a higher dopant concentration. After extrinsic base(s) 112b are formed where desired on intrinsic base 112a, Capping insulator 142 may be removed by stripping and/or any other technique to remove masking layer 142. Capping insulator 142, alternatively, may be left intact and etched during the forming of any contacts (e.g., emitter contact 126 (FIG. 1)) to emitter 118. Portions of first insulator 108a previously formed (e.g., as shown in FIG. 9) may further isolate extrinsic base 112b from emitter 118.

As shown in FIG. 1, further processing may include forming (or re-forming, where applicable) of second insulator 108b over extrinsic bases 112b, spacers 120, emitter 118, and vertically between collector(s) 106 and extrinsic base 112b. Second insulator 108b may be formed through a combination of deposition and etching, in which portions of second insulator 108b horizontally beyond collector extension regions 107 may be removed from the upper surface of subcollector 104 material. Additional second insulator material 108b may encapsulate extrinsic bases 112b, emitter 118, and/or spacer(s) 120 to create a formal spacer structure over the various materials discussed herein. Further processing to yield structure(s) 100 may include forming ILD material (e.g., third insulator 108c), forming openings in ILD material and filling them with conductor(s) to form contact(s) 122, 124, 126, and/or other processes suitable to yield bipolar transistor 110 discussed herein). In still further examples, methods of the disclosure may be modified to omit certain steps and/or not perform certain steps on multiple areas, e.g., only one extrinsic base 112b may be formed by performing the methods discussed herein over a reduced surface area.

Embodiments of the disclosure provide various technical and commercial advantages, examples of which are discussed herein. Embodiments of the disclosure are operable to form discontinuous barrier film 116 to prevent migration of dopants from emitter 118 into base 112, but without significant additional processing to form bipolar transistor 110. Embodiments of the disclosure, in particular, modify conventional vertical bipolar transistor processing to include the forming of discontinuous barrier film 116 without significant further modifications. The presence of discontinuous barrier film 116 will trap and prevent further migration of dopants (e.g., As as discussed herein) from emitter 118 into intrinsic base 112a, while preserving the electrical interface between intrinsic base 112a and emitter 118 in bipolar transistor 110. The reduced migration of dopants, in turn, increases the emitter-base breakdown voltage of bipolar transistor 110 and thus improves its versatility for implementation in various products.

Applicant has determined that embodiments of structure 100 also offer reduced base-emitter resistance within bipolar transistor structure 110 as compared to conventional bipolar transistors, notwithstanding the addition of discontinuous barrier film 116 between intrinsic base 112a and emitter 118.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a discontinuous barrier film vertically interposed between an emitter and a base of a bipolar transistor.

2. The structure of claim 1, wherein the discontinuous barrier film includes an oxide-based material.

3. The structure of claim 2, wherein a concentration of oxide within the discontinuous barrier film is non-uniform with respect to horizontal position.

4. The structure of claim 1, further comprising:
an insulator on a portion of the base of the bipolar transistor and horizontally adjacent the discontinuous barrier film; and
a spacer on the insulator and horizontally adjacent the emitter of the bipolar transistor,
wherein the discontinuous barrier film is below the spacer.

5. The structure of claim 4, wherein a combined horizontal span of the discontinuous barrier film is at least half of a horizontal span between a first portion of the insulator and a second portion of the insulator.

6. The structure of claim 1, wherein the emitter includes an arsenic-doped silicon (As—Si) layer and the base includes silicon (Si).

7. The structure of claim 6, wherein at least one As—Si to Si interface is present along a length of the discontinuous barrier film.

8. A structure comprising:
a heterojunction bipolar transistor (HBT) structure including:
a collector terminal within a semiconductor substrate;
a base terminal on the collector terminal;
an emitter terminal over the base terminal; and
a discontinuous barrier film vertically interposed between the emitter terminal and the base of the heterojunction bipolar transistor.

9. The structure of claim 8, wherein the discontinuous barrier film includes an oxide-based material.

10. The structure of claim 9, wherein a concentration of oxide within the discontinuous barrier film is non-uniform with respect to horizontal position.

11. The structure of claim 8, further comprising:
an insulator on a portion of the base terminal of the HBT and horizontally adjacent the discontinuous barrier film; and
a spacer on the insulator and horizontally adjacent the emitter terminal of the HBT,
wherein the discontinuous barrier film is below the spacer.

12. The structure of claim 11, wherein a combined horizontal span of the discontinuous barrier film is at least half of a horizontal span between a first portion of the insulator and a second portion of the insulator.

13. The structure of claim 8, wherein the emitter includes an arsenic-doped silicon (As—Si) layer and the base includes silicon (Si).

14. The structure of claim 13, wherein at least one As—Si to Si interface is present along a length of the discontinuous barrier film.

15. A method comprising:
forming a collector terminal within a semiconductor substrate;
forming a base terminal on the collector terminal;
forming a discontinuous barrier film on the base terminal; and
forming an emitter terminal over the base terminal and the discontinuous barrier film to define a bipolar transistor, wherein the discontinuous barrier film is vertically interposed between the emitter terminal and the base of the bipolar transistor.

16. The method of claim 15, wherein forming the discontinuous barrier film includes forming an oxide-based material on the base terminal.

17. The method of claim 16, wherein a concentration of oxide within the discontinuous barrier film is non-uniform with respect to horizontal position.

18. The method of claim 17, further comprising:
forming an insulator on a portion of the base of the bipolar transistor and horizontally adjacent the discontinuous barrier film; and
forming a spacer on the insulator and horizontally adjacent the emitter of the bipolar transistor,
wherein the discontinuous barrier film is below the spacer.

19. The method of claim 15, wherein the emitter includes an arsenic-doped silicon (As—Si) layer and the base includes silicon (Si).

20. The method of claim 19, wherein at least one As—Si to Si interface is present along a length of the discontinuous barrier film.
